(19) United States
(12) Patent Application Publication
(10) Pub. No.: US 2015/0221738 A1
(43) Pub. Date: Aug. 6, 2015

(54) SEMICONDUCTOR DEVICE AND METHOD OF OPERATING THE SAME

(71) Applicant: SK hynix Inc., Gyeonggi-do (KR)

(72) Inventor: Young Soo AHN, Gyeonggi-do (KR)

(21) Appl. No.: 14/314,979

(22) Filed: Jun. 25, 2014

(30) Foreign Application Priority Data
Feb. 4, 2014 (KR) 10-2014-0012684

(51) Int. Cl. H01L 29/423; H01L 29/78; G11C 16/14; H01L 27/115

(52) U.S. Cl. CPC H01L 29/42376; H01L 27/115; H01L 29/7827; G11C 16/14

(57) ABSTRACT

A semiconductor device including a channel layer, a gate insulating layer formed on a surface of the channel layer, a cell gate pattern formed along the gate insulating layer, and an Electro Migration (EM) pattern formed in the cell gate pattern, and movable by an electric field formed between the cell gate pattern and the channel layer.

### CROSS-REFERENCE TO RELATED APPLICATION

The present application claims priority to Korean patent application number 10-2014-0012684, filed on Feb. 4, 2014, the entire disclosure of which is incorporated herein in its entirety by reference.

### BACKGROUND

1. Field of Invention

Various exemplary embodiments of the present invention relate generally to a semiconductor device and a method of operating the same, and more particularly, to a memory device including a nonvolatile memory device and a method of operating the same.

2. Description of Related Art

A non-volatile memory device maintains stored data even without a power supply. A flash memory type nonvolatile memory device is widely used in digital cameras, computers, mobile communication terminals, memory cards, and the like. A NAND flash memory device includes a plurality of memory cells serially connected between a bit line and a source line to configure one memory string. The memory string structure of the NAND flash memory device is advantageous to integration.

In general, the NAND flash memory device changes threshold voltages of memory cells by controlling the amount of charge stored in the floating gates, thereby implementing an erase state or a program state. As the size of semiconductor memory devices has been reduced, there has been increased characteristic deterioration in NAND flash memory devices, including the aforementioned memory string structure. Accordingly, it is necessary to develop new nonvolatile memory devices to cope with the, characteristic deterioration from various causes.

### SUMMARY

Various exemplary embodiments of the present invention are directed to a semiconductor device using Electro Migration (EM) and a method of operating the same.

An embodiment of the present invention may provide a semiconductor device including a channel layer, a gate insulating layer formed on a surface of the channel layer, a cell gate pattern formed along the gate insulating layer, and an Electro Migration (EM) pattern formed in the cell gate pattern, and movable according to an electric field formed between the cell gate pattern and the channel layer.

Another embodiment of the present invention may provide a method of operating a semiconductor device including performing a program operation on a memory cell, which includes a channel layer, a gate insulating layer formed on a surface of the channel layer, a gate pattern formed along the gate insulating layer, and an EM pattern formed in the gate pattern, by applying a first voltage to the channel layer, and a second voltage to the gate pattern so that an air gap is formed between the EM pattern and the gate insulating layer.

Yet another embodiment of the present invention may provide a method of operating a semiconductor device including performing an erase operation on a memory cell, which includes a channel layer, a gate insulating layer formed on a surface of the channel layer, a gate pattern formed along the gate insulating layer, and an EM pattern formed in the gate pattern, by applying a third voltage to the channel layer, and a fourth voltage to the gate pattern so that an air gap is formed between the EM pattern and the gate pattern and the EM pattern is in contact with the gate insulating layer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and advantages of the present invention will become more apparent to those of ordinary skill in the art by describing in detail embodiments thereof with reference to the attached drawings in which:

FIGS. 1A and 1B are cross-sectional views illustrating a memory cell of a semiconductor device according to an exemplary embodiment of the present invention;

FIGS. 2 and 3 are cross-sectional views illustrating a method of operating the semiconductor device according to an exemplary embodiment of the present invention;

FIG. 4 is a perspective view illustrating a semiconductor device according to an exemplary embodiment of the present invention;

FIGS. 5A and 5B are cross-sectional views illustrating a memory cell and a select transistor shown in FIG. 4;

FIGS. 6A to 6I are cross-sectional views illustrating a method of manufacturing a semiconductor device according to the exemplary embodiment of the present invention;

FIG. 7 is a cross-sectional view illustrating a semiconductor device according to an exemplary embodiment of the present invention;

FIG. 8 is a perspective view illustrating a semiconductor device according to an exemplary embodiment of the present invention;

FIG. 9 is a cross-sectional view illustrating a semiconductor device according to an exemplary embodiment of the present invention;

FIG. 10 is a cross-sectional view illustrating a semiconductor device according to an exemplary embodiment of the present invention;

FIG. 11 is a block diagram illustrating a memory system according to an exemplary embodiment of the present invention; and

FIG. 12 is a block diagram illustrating a computing system according to an exemplary embodiment of the present invention.

### DETAILED DESCRIPTION

Hereinafter, the most preferable embodiment of the present invention will be described. In the drawings, the thicknesses and the lengths of elements may be exaggerated for convenience of illustration. In describing the present invention, configurations, structures, and methods that are commonly known to those skilled in the art may be omitted to avoid obscuring the present invention. Throughout the drawings, like reference numerals refer to like elements.

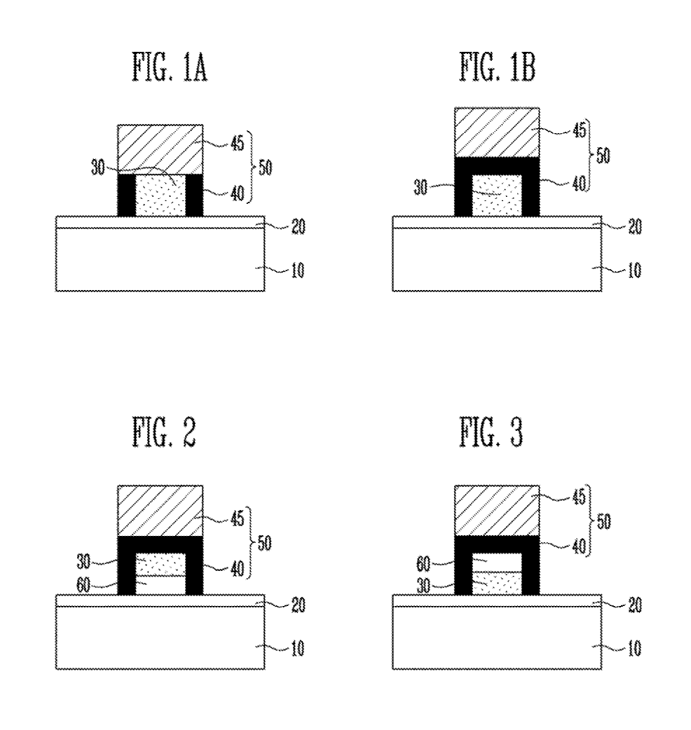

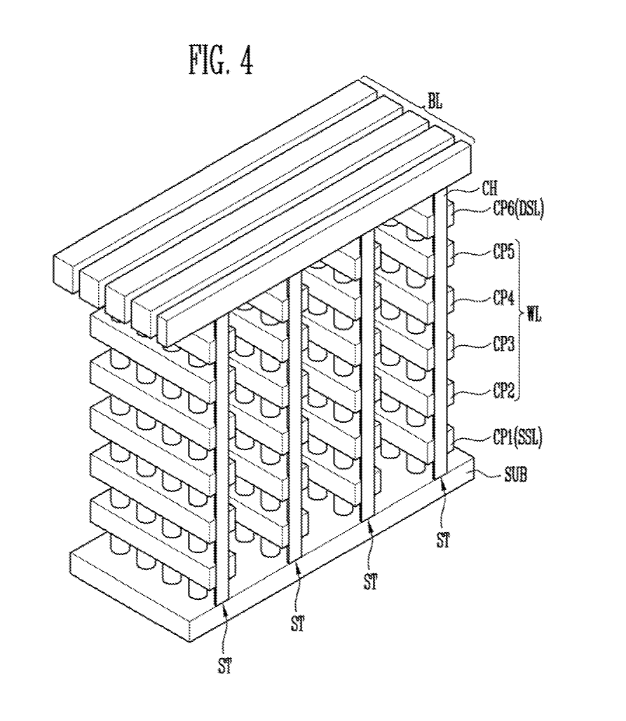

FIGS. 1A and 1B are cross-sectional views illustrating a memory cell of a semiconductor device according to an exemplary embodiment of the present invention. A semiconductor device according to an exemplary embodiment of the present invention may be a nonvolatile memory device.

As illustrated in FIGS. 1A and 1B, the semiconductor device according to an exemplary embodiment of the present invention may include a channel layer 10 a gate insulating layer 20 formed on a surface of the channel layer 10, a gate pattern 50 formed along the gate insulating layer 20, and an Electro Migration (EM) pattern 30 formed in the gate pattern 50.

The EM pattern 30 may include a plurality of surfaces, and one surface among the plurality of surfaces is opened by the gate pattern 50. The opened surface of the EM pattern 30 may be in contact with the gate insulating layer 20. The EM pattern 30 may move by an EM phenomenon generated by an electric field formed between the gate pattern 50 and the channel layer 10.

According to the EM phenomenon, an atom configuring a wire is pushed and moved by an electron when current flows through the wire. The EM pattern 30 may be formed of a metal that is easily subject to the EM phenomenon. For example, the EM pattern 30 may include aluminum, copper, or both aluminum and copper. The EM pattern 30 may store a program state or an erase state by moving toward the channel layer 10 or the gate insulating layer 20 according to the direction of the electric field applied between the channel layer 10 and the gate pattern 50. The gate insulating layer 20 may be formed of a silicon oxide layer or a high dielectric layer. The high dielectric layer may have a higher dielectric constant than that of the silicon oxide layer. For example, the high dielectric layer may include an aluminum oxide layer, a zirconium oxide layer, or a hafnium oxide layer.

The channel layer 10 may be a semiconductor layer formed in a straight pillar structure. The channel layer 10 may be formed of in a U-shaped structure comprising two or more straight pillar parts and a pipe part connecting the pillar parts. In addition, the channel layer 10 may be a semiconductor layer formed in various shapes. The channel layer 10 may be part of a semiconductor substrate. The channel layer 10 may be two or more stacked semiconductor layers with an interlayer insulating layer interposed therebetween.

The gate pattern 50 may be a word line connected to the memory cell. The gate pattern 50 may be formed to open one of the surfaces of the EM pattern 30 adjacent to the gate insulating layer 20 in order to allow an on-off operation of the memory cell according to the data storage state of the EM pattern 30. The gate pattern 50 may be formed of various materials in various forms. For example, the gate pattern 50 may be formed in an integrated conductive pattern. In this case, the gate pattern 50 may be formed of a conductive material that is non-responsive to the EM phenomenon. For example, the gate pattern 50 may include tungsten. The gate pattern 50 may include a first conductive pattern 40 and a second conductive pattern 45. More particularly, the first conductive pattern 40 may open one of the surfaces of the EM pattern 30 adjacent to the gate insulating layer 20, and be formed on the surface of the EM pattern 30. The second conductive pattern 45 may be formed to face the channel layer 10 and the gate insulating layer 20 with the EM pattern 30 and the first conductive pattern 40 interposed therebetween.

The first conductive pattern 40 may be formed of the same conductive material or a different conductive material from that of the second conductive pattern 45. The second conductive pattern 45 may be formed of a conductive material that is non-responsive to the EM phenomenon. For example, the second conductive pattern 45 may include tungsten. The first conductive pattern 40 may include tungsten, a barrier conductive layer, or both. For example, the barrier conductive layer may include one or more of Ti, TiN, Ta, and TaN. The first conductive pattern 40 may exist in various forms. For example, as illustrated in FIG. 1A, the first conductive pattern 40 may be formed to surround the surfaces of the EM pattern 30 except for on the surfaces where the EM pattern 30 is in contact with the gate insulating layer 20 and the second conductive pattern 45. Otherwise, as illustrated in FIG. 1B, the first conductive pattern 40 may be formed to surround the EM pattern 30 except for the surface where the EM pattern 30 is in contact with the gate insulating layer 20.

Hereinafter, a method of operating the semiconductor device according to an exemplary embodiment of the present invention will be described with reference to FIGS. 2 and 3. The semiconductor device according to the exemplary embodiment of the present invention may implement a program state or an erase state of a memory cell by inducing the EM phenomenon of the EM pattern 30.

FIG. 2 is a cross-sectional view illustrating the program state of the memory cell according to an exemplary embodiment of the present invention. As illustrated in FIG. 2, the program state may be implemented by inducing the EM phenomenon so that an air gap 60 formed between the EM pattern 30 and the gate insulating layer 20.

The EM phenomenon for implementing the program state may be induced through a program operation by applying first and second voltages to the channel layer 10 and the gate pattern 50, respectively. The second voltage may have a higher level than that of the first voltage, and thus an electric field flows from the gate pattern 50 to the channel layer 10. For example, the first voltage may be a ground voltage, and the second voltage may be a positive voltage. The second voltage may be higher than both the threshold voltage of the memory cell and the pass voltage to be described below.

FIG. 3 is a cross-sectional view illustrating the erase state of the memory cell according to an exemplary embodiment of the present invention. As illustrated in FIG. 3, the erase state may be implemented by inducing the EM phenomenon so that the EM pattern 30 is in contact with the gate insulating layer 20. When the EM pattern 30 is in contact with the gate insulating layer 20, the air gap 60 may be formed between the surface of the gate pattern 50, facing the gate insulating layer 20, and the EM pattern 30. For example, the air gap 60 may be formed between the second conductive pattern 45 and the EM pattern 30. In this case, one or more surfaces of the EM pattern 30 may be in contact with part of the gate pattern 50 to receive a voltage applied to the gate pattern 50. For example, the EM pattern 30 may be in contact with the first conductive pattern 40.

The EM phenomenon for implementing the erase state may be induced through an erase operation by applying third and fourth voltages to the channel layer 10 and the gate pattern 50, respectively. The third voltage may have a higher level than that of the fourth voltage, and thus an electric field flows from the channel layer 10 to the gate pattern 50. For example, the fourth voltage may be a ground voltage, and the third voltage may be a positive voltage.

When a read operation is performed on the memory cell which may be in the program state or the erase state, a read voltage may be applied to the gate pattern 50 of the memory cell. The read voltage may be lower than that of a pass voltage to be described below. A current path may bear may not be formed in the channel layer 10 of the memory cell, to which the read voltage is applied, according to data stored in the memory cell. Particularly, when the memory cell is in the program state as illustrated in FIG. 2, the EM pattern 30 may be spaced apart from the gate insulating layer 20 with the air gap 60 interposed therebetween, so that a channel or a current path may not be formed in the channel layer 10. When the memory cell is in the erase state as illustrated in FIG. 3, the read voltage applied to the gate pattern 50 may be transmitted to the EM pattern 30, and a channel or a current path may be formed in the channel layer 10 since the EM pattern 30 is in contact with the gate insulating layer 20. Accordingly, it is possible to read the program state or the erase state of the memory cell by determining whether the current path is formed in the channel layer 10. The level of the read voltage may be set to avoid forming a fringe field in the channel layer 10 in the program state, and set to form the channel within the channel layer 10 in the erase state.

In a case where the memory cell needs to be turned on, a pass voltage having a higher level than that of the read voltage may be applied to the gate pattern 50 of the memory cell. Even though the memory cell is in the program state as illustrated in FIG. 2, the pass voltage applied to the gate pattern 50 may induce a fringe field on the channel layer 10, thereby turning on the memory cell in the program state. Even though the memory cell is in the erase state as illustrated in FIG. 3, the pass voltage applied to the gate pattern 50 may be transmitted to the EM pattern 30, thereby turning on the memory cell in the erase state.

As described above, the memory cell according to the exemplary embodiment of the present invention may implement the program state and the erase state by using the EM phenomenon. Accordingly, the semiconductor device according to the exemplary embodiment of the present invention may improve data retention characteristics compared to a semiconductor device implementing the program state and the erase state by controlling a threshold voltage according to the amount of charge.

FIG. 4 is a perspective view illustrating a semiconductor device according to an exemplary embodiment of the present invention. Particularly, FIG. 4 illustrates a channel layer CH formed in a straight pillar structure. For a clearer description, the insulating layer and the EM pattern are not illustrated in FIG. 4.

Referring to FIG. 4, the semiconductor device or a nonvolatile memory device according to the exemplary embodiment of the present invention may include a substrate SUB including a source region (not illustrated), bit lines BL, channel layers CH connected between the substrate SUB and the bit line BL, and memory strings ST formed along the channel layers CH.

The source region may be a conductive thin film disposed on the substrate SUB, or an impurity—injected region formed in the substrate SUB. The bit line BL may be a conductive line spaced apart from the source region of the substrate SUB and disposed on the source region.

The memory string ST may include the channel layer CH, the memory cells serially connected along the channel layer CH, and first and second select transistors formed at both ends of the channel layer CH with the memory cells interposed therebetween. The channel layer CH corresponds to the channel layer 10 described above with reference to FIGS. 1A to 3. The channel layer CH may be formed in a straight pillar structure connected between the source region of the substrate SUB and the bit line BL. The memory cells and the select transistors may be connected to conductive lines CP1 to CP6, respectively.

The conductive lines CP1 to CP6 may be stacked along the channel layer CH while being spaced apart from each other between the substrate SUB and the bit line BL. One or more conductive lines (for example, CP1) from the lowermost layer among the conductive lines CP1 to CP6 may be used as a first select line SSL connected to a gate of the first select transistor, and one or more conductive lines (for example, CP6) from the uppermost layer may be used as a second select line DSL connected to a gate of the second select transistor. The conductive lines (for example, CP2 to CP5) between the first select line SSL and the second select line DSL may be used as word lines WL connected to gates of the memory cells. The word lines WL correspond to the gate pattern 50 described above with reference to FIGS. 1A to 3. The conductive lines CP1 to CP6 may be formed in a line pattern in a direction crossing the bit line BL.

The first select transistor may be defined at a crossing portion between the channel layer CH and the first select line SSL, the second select transistor may be defined at a crossing portion between the channel layer CH and the second select line SSL, and the memory cells may be defined at crossing portions between the channel layer CH and the word lines WL. Accordingly, the first select transistor, the memory cells, and the second select transistor configuring the memory string ST may be serially connected through the channel layer CH.

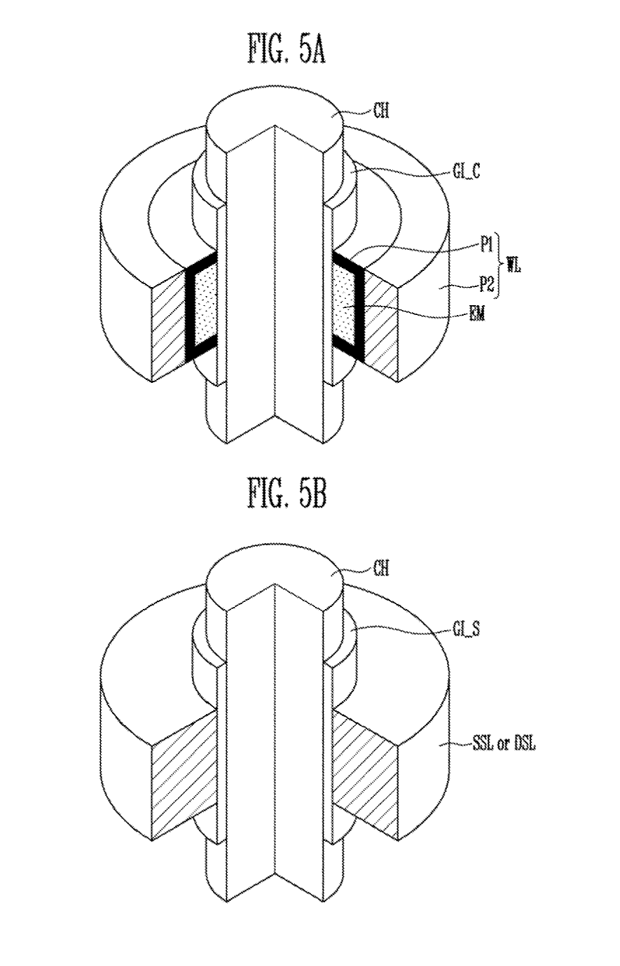

The memory cells may include the structure described above with reference to FIGS. 1A and 1B, and may be operated as described above with reference to FIGS. 2 and 3. The first and second select transistors may be formed in the same structure or a different structure from that of the memory cells. Hereinafter, structures of the memory cells and structures of the first and second select transistors according to the exemplary embodiment of the present invention will be described in more detail with reference to FIGS. 5A and 5B.

FIG. 5A is a cross-sectional view illustrating a memory cell shown in FIG. 4.

Referring to FIG. 5A, the memory cell may include the channel layer CH formed in the straight pillar structure, a gate insulating layer GI_C formed on a surface of the channel layer CH, a word I ne WL formed along the gate insulating layer GI_C, and an EM pattern EM formed within the word line WL. The gate insulating layer GI_C, the word line WL, and the EM pattern EM may surround the channel layer CH. The gate insulating layer GI_C, the EM pattern EM, and the word line WL may correspond to the gate insulating layer 20, the EM pattern 40, and the gate pattern 50 described above with reference to FIGS. 1A to 3, respectively.

The word line WL may include a first conductive pattern P1 and a second conductive pattern P2. The first conductive pattern P1 may open one surface of the EM pattern EM adjacent to the gate insulating layer GI_C and may be formed on a surface of the EM pattern EM. The second conductive pattern P2 may be formed to surround the channel layer CH with the EM pattern EM and the first conductive pattern P1 interposed therebetween. The first and second conductive patterns P1 and P2 may be formed of the same material as described above with reference to FIGS. 1A to 1B. The first conductive pattern P1 may be formed in various forms. For example, the first conductive pattern P1 may be formed to surround the surfaces of the EM pattern EM, except for the surface of the EM pattern EM adjacent to the channel layer CH. Although not illustrated in the drawing, the first conductive pattern P1 may be formed to surround the surfaces of the EM pattern EM, except for the first surface of the EM pattern EM contacting with the gate insulating layer GI_C and the second surface of the EM pattern EM facing the first surface.

FIG. 5B is a cross-sectional view illustrating the first and second select transistors shown in FIG. 4.

Referring to FIG. 5B, the first select transistor may include a gate insulating layer GI_S and the first select line SSL surrounding the channel layer CH formed in the straight pillar structure, and the second select transistor may include the gate insulating layer GI_S and the second select line DSL surrounding the channel layer CH formed in the straight pillar structure. The gate insulating layers GI_S of the first and second select transistors may be formed of a silicon oxide layer. The first and second select lines SSL and DSL may be formed of the same conductive material or a different conductive material from that of the world line WL. For example, the first and second select lines SSL and DSL may be formed of the same conductive material as that of the second conductive pattern P2, or silicon. Unlike the memory cells illustrated in FIG. 5A, the first and second select transistors may not include the EM pattern EM, and the first and second select lines SSL and DSL may be formed to be in contact with the gate insulating layer GI_S.

The structure of the memory cell illustrated in FIG. 5A and the structure of the first and second select transistors illustrated in FIG. 5B may be applied to the memory string ST illustrated in FIG. 4.

As another exemplary embodiment of the present invention, the first and second select transistors may be identically formed to the structure of the memory cell illustrated in FIG. 5A. According to this embodiment, an operation voltage applied to the first and second select lines of the first and second select transistors may be different from an operation voltage applied to the word line WL of the memory cell. The operation voltage applied to the first and second select lines may be controlled so that the EM phenomenon may not be induced within the first and second select transistors.

Hereinafter an operation of the nonvolatile memory device will be described in more detail with reference to FIGS. 4 to 5B. As illustrated in FIG. 4, a plurality of memory strings ST may be connected between the plurality of bit lines BL and the substrate SUB, Hereinafter, the memory string including a selected memory cell is referred to as a selected memory string, and a bit line connected to the selected memory string is referred to as a selected bit line. The second select transistor of the selected memory string is referred to as a selected second select transistor, The second select line connected to the selected second select transistor is referred to as a selected second select line. A word line connected to the selected memory cell is referred to as a selected word line, and the remaining word lines may be referred to as unselected word lines. A memory string, which is connected to the selected bit line, but is not selected, is referred to as an inhibited memory string. The memory string connected to an unselected bit line and the selected second select line is referred to as a first unselected memory string, and a memory string connected to the unselected bit line and an unselected second select line is referred to as a second unselected memory string.

During a program operation, a first voltage (for example, ground voltage) may be applied to the selected bit line, and a voltage (for example, Vcc) having a higher level than that of a threshold voltage of the second select transistor may be applied to the selected second select line. In this case, the second select transistor is turned on, and the first voltage of the selected bit line may be transmitted to a channel layer of the selected string.

Further, during the program operation, a second voltage may be applied to the selected word line of the selected string, and the pass voltage may be applied to the unselected word lines. The EM phenomenon of the EM pattern EM may be induced toward the second conductive pattern P2 of the word line WL due to the second voltage, which may be a program voltage. The pass voltage may have a lower level than that of the second voltage and a higher level than that of the threshold voltage of the memory cell.

An off voltage (for example, a ground voltage) may be applied to the first select line SSL. Accordingly, the first select transistors may be turned off, and an electrical connection between the channel layer CH and the source region of the substrate SUB may be blocked.

During the program operation, the off voltage (for example, the ground voltage) may be applied to the unselected second select line. Accordingly, the inhibited memory string and the second select transistors of the second unselected memory string may be turned off. As a result, the channel layers of the inhibited memory string and the second unselected memory string may be electrically disconnected with the bit lines, or floated.

During the program operation, a predetermined voltage (for example, Vcc) may be applied to the unselected bit lines. Accordingly, the same voltage may be applied to a drain and a gate of the second select transistor of a first unselected string, and a channel layer of the first unselected string has a potential corresponding to a difference of the voltage Vcc and a threshold voltage Vth (Vcc−Vth). Under that condition, when the program voltage and the pass voltages are applied to the word lines, the channel layer of the first unselected string has a potential higher than the difference (Vcc−Vth), and the second select transistor of the first unselected string may be shut off. Accordingly, the potential of the channel layer of the first unselected string may be boosted, and the EM phenomenon may not be induced by a potential level between the channel layer of the first unselected string and the selected word line.

The selected memory cell may be programmed as illustrated in FIG. 2 according to the program operation described above.

During an erase operation, the second select transistor may be turned on and a fourth voltage may be applied to the word lines WL so that a third voltage applied to the bit line BL may be transmitted to the channel layer. In this case, the substrate SUB and the first select line may be floated. The EM phenomenon of the EM pattern EM may be induced toward the gate insulating layer GI_C by the third voltage. The memory cell may be erased as illustrated in FIG. 3 according to the erase operation described above.

During a read operation, the selected bit line may be pre-charged with a predetermined voltage level, and a reference voltage (for example, 0 V) may be applied to the source region of the substrate SUB. Further, the first and second select transistors of the selected memory string may be turned on, and the read voltage may be applied to the selected word line, and the pass voltage higher than the read voltage may be applied to the unselected word lines. The read voltage may be set to have a level, by which the channel or the current path may be formed within the channel layer in the erase state and may not be formed in the program state. Accordingly, formation of the current path of the selected memory string may depend on formation of the current path within the channel layer of the selected memory cell according to data stored in the selected memory cell, which is described above with reference to FIGS. 2 and 3. The potential of the selected bit line may depend on formation of the current path of the selected memory string. The data stored in the selected memory cell may be read out by sensing the change of the potential of the bit line.

The memory cells connected to the unselected word lines, to which the pass voltage is applied, may be in the erase state or the program state. The memory cell in the program state, to which the pass voltage is applied, may be turned on because of a fringe field formed in the channel layer by the pass voltage. The memory cell in the erase state, to which the pass voltage is applied, may be turned on by the pass voltage.

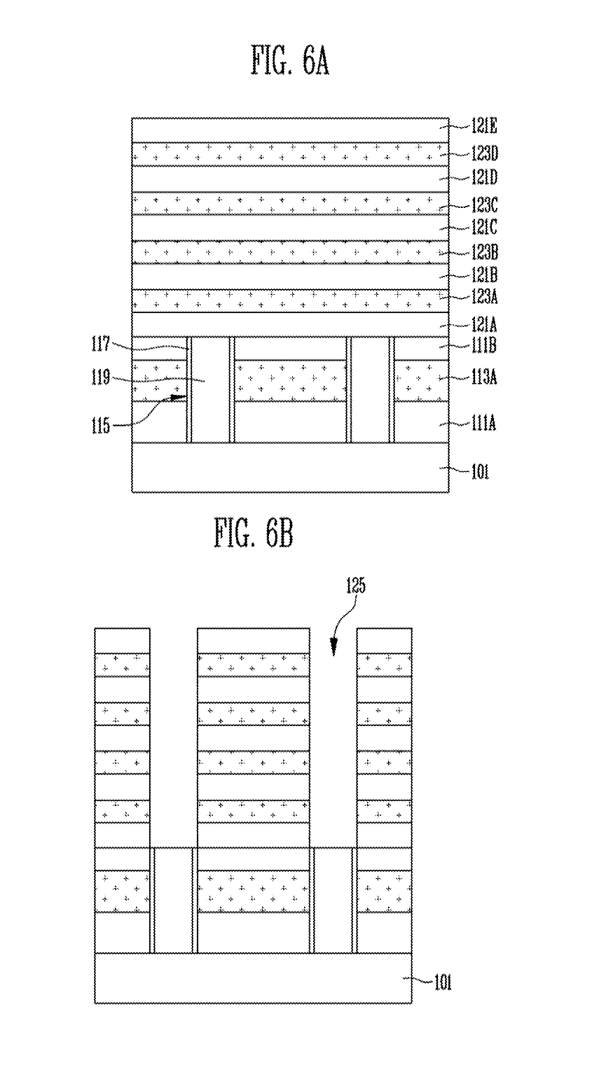

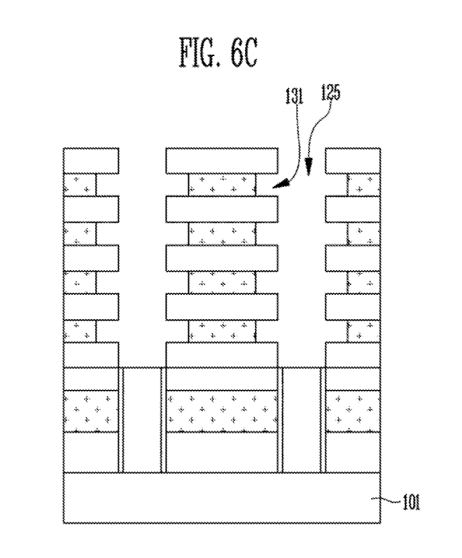

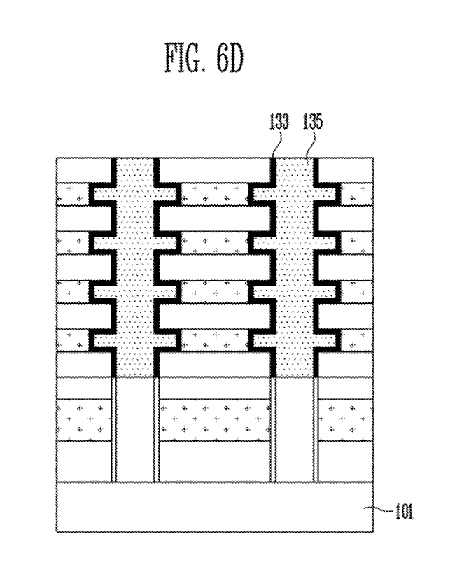

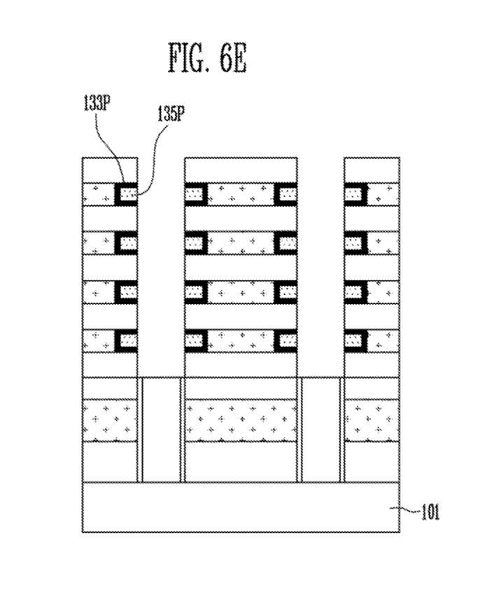

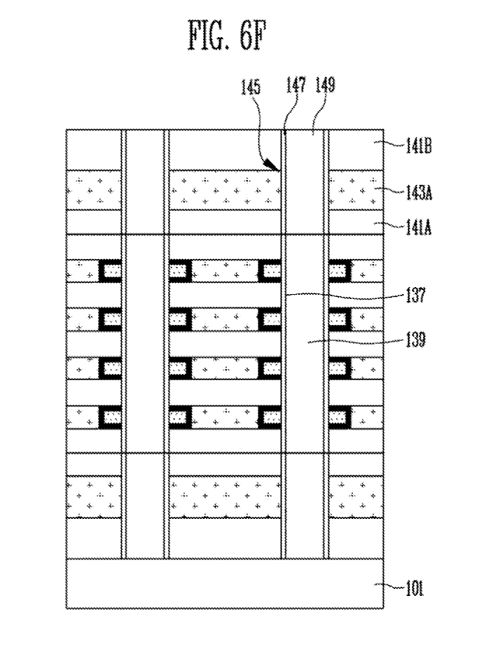

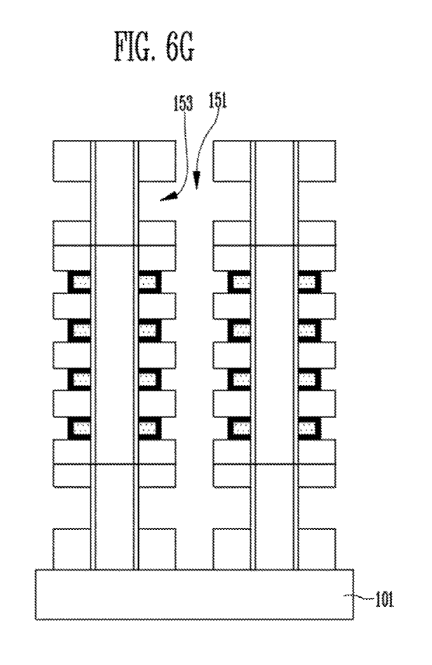

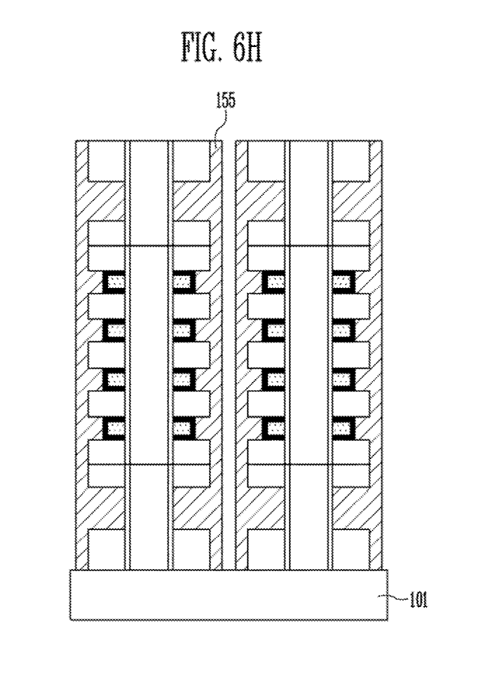

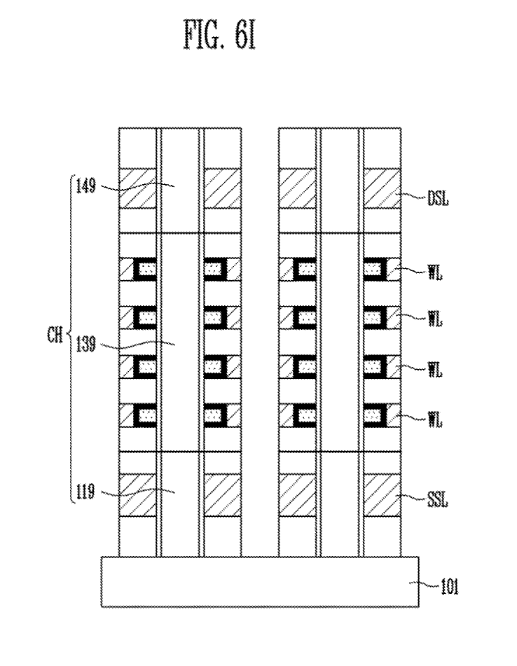

FIGS. 6A to 6I are cross-sectional views illustrating a method of manufacturing the semiconductor device according to the exemplary embodiment of the present invention. Particularly, FIGS. 6A to 6I illustrate an example of a method of manufacturing the nonvolatile memory device illustrated in FIGS. 4 to 5B.

Referring to FIG. 6A, first material layers 111A and 111B and one or more second material layer 113A may be alternately stacked on a substrate 101. The substrate 101 may be a semiconductor material. The substrate 101 may include a source region (not illustrated). The second material layer 113A may be formed on a region where a first select line is to be formed.

The first material layers 111A and 111B and the second material layer 113A may be formed of various materials. For example, the first material layers 111A and 111B may be formed of an insulating material for an interlayer insulating layer, and the second material layer 113A may be formed of a sacrificial material having etch selectivity for the first material layers 111A and 111B. In this case, the first material layers 111A and 111B may be formed of silicon oxide layers, and the second material layer 113A may be formed of a nitride layer. For another example, the first material layers 111A and 111B may be formed of an insulating material for an interlayer insulating layer, and the second material layer 113A may be formed of a conductive material.

Next, first through regions 115 passing through the first material layers 111A and 111B and the second material layer 113A may be formed by etching the first material layers 111A and 111B and the second material layer 113A. The cross-section of the first through region 115 may exist in various shapes, such as a circular shape, an elliptical shape, and a polygonal shape. The first through regions 115 may open the source region of the substrate 101.

Subsequently, first gate insulating layers 117 may be formed along lateral walls of the first through regions 115. Then, first channel portions 119 connected to the substrate 101 may be formed in the first through regions 115. The fire channel portions 119 may be formed of semiconductor layers filled up to center regions of the first through regions 115, or may be formed of semiconductor layers in a tube shape opening the center regions of the first through regions 115. A center region of the semiconductor layer having a tube shape may be filled with an insulating layer (not illustrated).

Then, third material layers 121A to 121E and fourth material layers 123A to 123D may be alternately stacked on the first material layers 111A and 111B and the second material layer 113A, through which the first channel portions 119 pass. The third material layers 121A to 121E may be formed of the same material as the first material layers 111A and 111B and the fourth material layers 123A to 123D may be formed of a sacrificial material having an etch selectivity for the third material layers 121A to 121E, or a conductive material, such as tungsten that is non-responsive to the EM phenomenon. A nitride layer may be used for the sacrificial material. The fourth material layers 123A to 123D may be formed in regions where the word lines are to be formed.

Referring to FIG. 6B, second through regions 125 passing through the third material layers 121A to 121E and the fourth material layers 123A to 123D may be formed by etching the third material layers 121A to 121E and the fourth material layers 123A to 123D. The second through regions 125 may be connected to the first through regions 115, and may open the first channel portions 119.

Referring to FIG. 6C, first recess regions 131 may be formed by selectively etching the third material layers 121A to 121E opened through lateral walls of the second through regions 125.

Referring to FIG. 6D, first conductive layers 133 may be formed along surfaces of the first recess regions 131 and the second through regions 125. Next, partial regions of the first conductive layers 133 formed on upper surfaces of the first channel portions 119 may be removed by an etching process.

Then, metal layers 135 may be filled in the first recess regions 131 and the second through regions 125 covered by the first conductive layers 133. The metal layers 135 may include a material such as aluminum and copper that is easily subject to the EM phenomenon.

Referring to FIG. 6E, the first conductive layers 133 and the metal layers 135 in the second through regions 125 may be removed by etching the first conductive layers 133 and the metal layers 135. Accordingly, the first conductive layers 133 may be left as first conductive patterns 135P, which are separated from each other, in the first recess regions 131, and the metal layers 135 may be left as EM patterns 135P, which are separated from each other, in the first recess regions 131.

Referring to FIG. 6F, second gate insulating layers 137 may be formed along lateral walls of the second through regions 125. Then, second channel portions 139 connected to the first channel portions 119 may be formed in the second through regions 125. The second channel portions 139 may be formed of semiconductor layers filled up to center regions of the second through regions 125, or may be formed of semiconductor layers in a tube shape opening the center regions of the second through regions 125. A center region of the semiconductor layer having a tube shape may be filled with an insulating layer (not illustrated).

Then, fifth material layers 141A and 141B and one or more sixth material layer 143A may be alternately stacked on the third material layers 121A to 121E and the fourth material layers 123A to 123D, through which the second channel portions 139 pass. The sixth material layer 143A may be formed on a region in which a second select line is to be formed.

The fifth material layers 141A and 141B may be formed of the same material as that of the first material layers 111A and 111B, and the sixth material layer 143A may be formed of the same material as that of the second material layer 113A. Next, third through regions 145 passing through the fifth material layers 141A and 141B and the sixth material layer 143A may be formed by etching the fifth material layers 141A and 141B and the sixth material layer 143A. The third through region 145 may exist in various cross-sectional shapes, such as a circular shape, an elliptical shape, and a polygonal shape. The third through regions 145 may open the second channel portions 139.

Then, third gate insulating layers 147 may be formed along lateral walls of the third through regions 145. Subsequently, third channel portions 149 connected to the second channel portions 139 may be formed in the third through regions 145. The third channel portions 149 may be formed of semiconductor layers filled up to center regions of the third through regions 145, or may be formed of semiconductor layers in a tube shape opening the center regions of the third through regions 145. A center region of the semiconductor layer having the tube shape may be filled with an insulating layer (not illustrated).

The subsequent process may vary according to properties of the second material layer 113A, the fourth material layers 123A to 123D, and the sixth material layer 143A. First, in a case where the second material layer 113A, the fourth material layers 123A to 123D, and the sixth material layer 143A are formed of a conductive material, a slit (not illustrated) may be formed. The slit may pass through the first to sixth material layers 111A, 111B, 113A, 121A to 121E, 123A to 123D, 141A, 141B and 143A to separate the first to sixth material layers 111A, 111B, 113A, 121A to 121E, 123A to 123D, 141A, 141B, and 143A by a memory block unit or for each line pattern. In this case, the second material layer 113A, the fourth material layers 123A to 123D, and the sixth material layer 143A may be separated into patterns corresponding to the conductive patterns CP1 to CP6 illustrated in FIG. 4 by the slit. Then, a subsequent process for forming the bit line (not illustrated) may be performed.

Unlike the above description, in a case where the second material layer 113A, the fourth material layers 123A to 123D, and the sixth material layer 143A may be formed of a sacrificial material, the subsequent processes follow FIGS. 6G to 6I.

Referring to FIG. 6G, the fifth and sixth material layers 141A, 141B, and 143A between the third through regions 145, the third and fourth material layers 121A to 121E, and 123A to 123D between the second through regions 125, and the first and second material layers 111A, 111B, and 113A between the first through regions 115 may be etched. Accordingly, a slit 151, which passes through the first to sixth material layers 111A, 111B, 113A, 121A to 121E, 123A to 123D, 141A, 141B, and 143A and opens the second material layer 113A, the fourth material layers 123A to 123D, and the sixth material layer 143A, may be formed.

After forming the slit 151, second recess regions 153 may be formed by selectively removing the second material layer 113A, the fourth material layers 123A to 123D, and the sixth material layer 143A. Although it is not illustrated in the drawing, in order to form the structure of the memory cell described above with reference to FIG. 1A, the EM patterns 135P may be exposed by partially removing the first conductive patterns 133P exposed through the second recess regions 153.

Referring to FIG. 6H, a second conductive layer 155 may be filled in the second recess regions 153. The second conductive layer 155 may be formed of a metal, such as tungsten, that is non-responsive to the EM phenomenon.

Referring to FIG. 6I, a part of the second conductive layer 155 within the slit 151 may be removed by etching the second conductive layer 155. Accordingly, the second conductive layer may be left as second conductive patterns, which are separated from each other, in the second recess regions 153. Accordingly, conductive lines SSL, WL, and DSL including the first select line SSL, the word lines WL and the second select line DSL described above with reference to FIGS. 4 to 5B may be formed. The first select line SSL, the word lines WL, and the second select line DSL may surround the channel layer CH formed in the straight pillar structure. The straight pillar structure includes the first, second, and third channel portions 119, 139 and 149 surrounded by the first select line SSL, the word lines WL, and the second select line DSL, respectively. Then, a subsequent process for forming the bit line (not illustrated) may be performed.

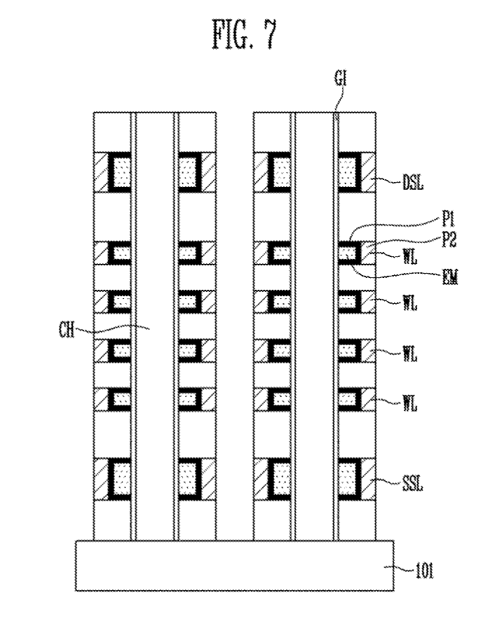

FIG. 7 is a cross-sectional view illustrating a semiconductor device according to an exemplary embodiment of the present invention. Particularly, FIG. 7 illustrates a semiconductor device having the select transistors illustrated in FIG. 4 of the same structures as the memory cells.

Referring to FIG. 7, conductive patterns including first and second select lines SSL and DSL and word lines WL may be stacked while surrounding a channel layer CH surrounded by a gate insulating layer GI. An interlayer insulating layer may be formed between the neighboring conductive patterns DSL, SSL, and WL. The first select line SSL and the second select line DSL may be disposed at both ends of the channel layer CH with the word lines WL interposed therebetween.

An EM pattern EM may be formed in each of the word lines WL, which may include a first conductive pattern P1 and a second conductive pattern P2. The first conductive pattern P1 may open one surface of the EM pattern EM adjacent to the gate insulating layer GI, and may be formed on a surface of the EM pattern EM. The second conductive pattern P2 may be formed to surround the channel layer CH with the EM pattern EM and the first conductive pattern P1 interposed therebetween.

The first and second select lines SSL and DSL may be formed of the same structure as those of the word lines WL and the same structure as that of the EM pattern EM.

The EM pattern EM, word lines WL, first select line SSL, and second select line DSL may be formed through the processes described above with reference to FIGS. 6A to 6I. The first select line SSL and the second select line DSL may be simultaneously formed with the word lines WL through the same process as the word lines WL.

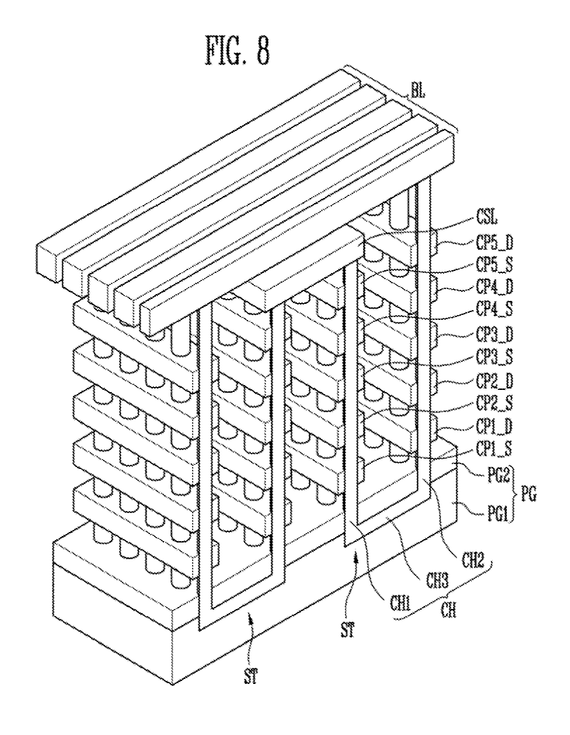

FIG. 8 is a perspective view illustrating a semiconductor device according to an exemplary embodiment of the present invention. Particularly, FIG. 8 illustrates a U-shaped channel layer CH comprising a pair of straight pillar parts CH1 and CH2 and a pipe part CH3 connecting the pillar parts CH1 and CH2. For a clearer description, the insulating layer and the EM pattern are not illustrated in FIG. 8.

Referring to FIG. 8 the semiconductor device or a nonvolatile memory device according to an exemplary embodiment of the present invention may include bit lines BL, a common source line CSL, and memory strings ST formed along the U-shaped channel layers CH connected between the bit lines BL and the common source line CSL.

The bit line BL and the common source line CSL may be conductive patterns formed while being spaced apart from each other. The bit line BL and the common source line CSL may be disposed on the channel layer CH. The bit lines BL may be connected onto one end of the channel layer CH, and the common source line CSL may be connected to the other end of the channel layer CH.

The memory string ST may include the channel layer CH, memory cells serially connected along the channel layer CH, and first and second select transistors formed at both ends of the channel layer CH with the memory cells interposed therebetween. The channel layer CH corresponds to the channel layer 10 described above with reference to FIGS. 1A to 3. In the U-shaped channel layer CH, the straight first pillar part CH1 may be connected to the common source line CSL, the straight second pillar part CH2 may be connected to the bit line BL, and the pipe part CH3 connecting the first pillar part CH1 and the second pillar part CH2.

The first pillar part CH1 may be surrounded by source-side conductive lines CP1_S to CP5_S. The source-side conductive lines CP1_S to CP5_S may be spaced apart from each other along the first pillar part CH1. One or more conductive lines (for example, CP5_5) from the uppermost layer among the source-side conductive lines CP1_S to CP5_S may be used as the first select line SSL connected to a gate of the first select transistor, and the remaining conductive lines CP1_S to CP4_S may be used as the word lines WL

The second pillar part CH2 may be surrounded by drain-side conductive lines CP1_D to CP5_D. The drain-side conductive lines CP1_D to CP5_D may be spaced apart from each other along the second pillar part CH2. One or more conductive lines (for example, CP5_D) from the uppermost layer among the drain-side conductive lines CP1_D to CP5_D may be used as the second select line DSL connected to a gate of the second select transistor, and the remaining conductive lines CP1_D to CP4_D may be used as the word lines WL.

In the above description, the word lines WL correspond to the gate pattern 50 described above with reference to FIGS. 1A to 3. The source-side conductive lines CP1_S to CP5_S and the drain-side conductive lines CP1_D to CP5_D may be formed in a line pattern in a direction crossing the bit line BL. The EM patterns EM may be formed in the word lines WL as described above with reference to FIG. 5A, and the channel layer CH may be surrounded by a gate insulating layer GI_C as described above with reference to FIG. 5A. A gate insulating layer GI_S may be formed between the first select line SSL and the channel layer CH, and between the second select line DSL and the channel layer CH as described above with reference to FIG. 5B. The first and second select lines SSL and DSL may be formed in a different structure from that of the word line WL as described above with reference to FIG. 5B. As another exemplary embodiment of the present invention, the first and second select lines SSL and DSL may include the same structure as that of the EM pattern EM described above with reference to FIG. 5A and the same structure as that of the word line WL.

The pipe part CH3 may connect the first and second pillar parts CH1 and CH2 under the source-side conductive lines CP1_S to CP5_5 and the drain-side conductive lines CP1_D to CP5_D. The pipe part CH3 may be surrounded by a pipe gate PG with a pipe gate insulating layer (not illustrated) interposed therebetween. The pipe gate PG may include a first pipe gate PG1 surrounding a lower surface and lateral surfaces of the pipe part CH3, and a second pipe gate PG2 covering an upper surface of the pipe part CH3.

The first select transistor may be defined at a crossing portion between the channel layer CH and the first select line SSL, the second select transistor may be defined at a crossing portion between the channel layer CH and the second select line SSL, the memory cells may be defined at crossing portions between the channel layer CH and the word lines WL, and a pipe transistor may be defined at a crossing portion between the channel layer CH and the pipe gate PG. Accordingly, the first select transistor, the memory cells, the pipe transistor, and the second select transistor configuring the memory string ST may be serially connected through the channel layer CH.

The operation of the memory string including the structure illustrated in FIG. 8 may be similar to the operation of the memory string described above with reference to FIGS. 1 to 5B.

Further, a method of manufacturing the memory string including the structure illustrated in FIG. 8 may be similar to the method described above with reference to FIGS. 6A to 6I after forming the pipe gate PG and the pipe portion CH3.

FIG. 9 is a cross-sectional view illustrating a semiconductor device according to an exemplary embodiment of the present invention.

Particularly, FIG. 9 illustrates a channel layer CH that is a partial region of a semiconductor substrate SUB, and memory cells arranged in a 2D structure.

Referring to FIG. 9, the semiconductor device or a nonvolatile memory device according to the exemplary embodiment of the present invention may include a first select line SSL, word lines WL, and a second select line DSL formed in parallel on the semiconductor substrate SUB. Gate insulating layers GI may be formed between the semiconductor substrate SUB and conductive lines including the first select line SSL, the word lines WL, and the second select line DSL. EM patterns EM may be formed in the world lines WL. The word lines WL may include a first conductive pattern P1 and a second conductive pattern P2. The first conductive pattern P1 and the second conductive pattern P2 may be formed in one of the structures described above with reference to FIGS. 1A and 1B.

Regions of the semiconductor substrate SUB overlapping the first select line SSL, the word lines WL, and the second select line DSL may serve as the channel layer CH. Junction regions JS, JC, and JD, into which an impurity is injected, may be formed within the semiconductor substrate SUB at both sides of the channel layer CH. The junction regions JS, JC and JD may include cell junction regions JC formed at both sides of each of the word lines WL a source region JS formed at one side of the first select line SSL, and a drain region JD formed at one side of the second select line DSL. The source region JS may be connected to a source contact line SCT. The drain region JD may be connected with a bit line BL via drain contact plugs DCT.

According to the above-described structure, a first select transistor, memory cells, and a second select transistor, which are serially connected by the junction regions JS, JC, and JD, may configure one memory string, and may be two-dimensionally arranged on the semiconductor substrate SUB.

The operation of the memory string including the structure illustrated in FIG. 9 may be similar to the operation of the memory string described above with reference to FIGS. 1 to 5B.

An example of a method of manufacturing the memory string including the structure illustrated in FIG. 9 will be described below.

First, an insulating layer for the gate insulating layers GI may be formed on a semiconductor substrate SUB. Then, after a metal layer for the EM patterns EM is formed on the insulating layer, the EM patterns EM may be formed by patterning the metal layer. The metal layer may include aluminum or copper that is easily subject to the EM phenomenon.

Then, first conductive pattern P1 may be formed along lateral wall of the EM pattern EM. As another embodiment, the first conductive pattern P1 may be formed along the lateral wall and an upper surface of the EM pattern EM. The first conductive pattern P1 may include the same conductive material as that of the second conductive pattern P2, or include one or more of Ti, TIN, Ta, and TaN.

Next, a second conductive layer may be formed, and the first select line SSL, the word lines WL, and the second select line DSL may be formed by patterning the second conductive layer. The second conductive layer may be formed of a metal, for example tungsten, that is non-responsive to the EM phenomenon. The gate insulating layers GI may be patterned during the process of patterning the second conductive layer. Then, the junction regions JS, JC, and JD may be formed by injecting an impurity into the semiconductor substrate SUB by using the first select line SSL, the word lines WL, and the second select line DSL as a mask.

Next, the drain contact plugs DCT, the source contact line SCT, and the bit line BL may be formed.

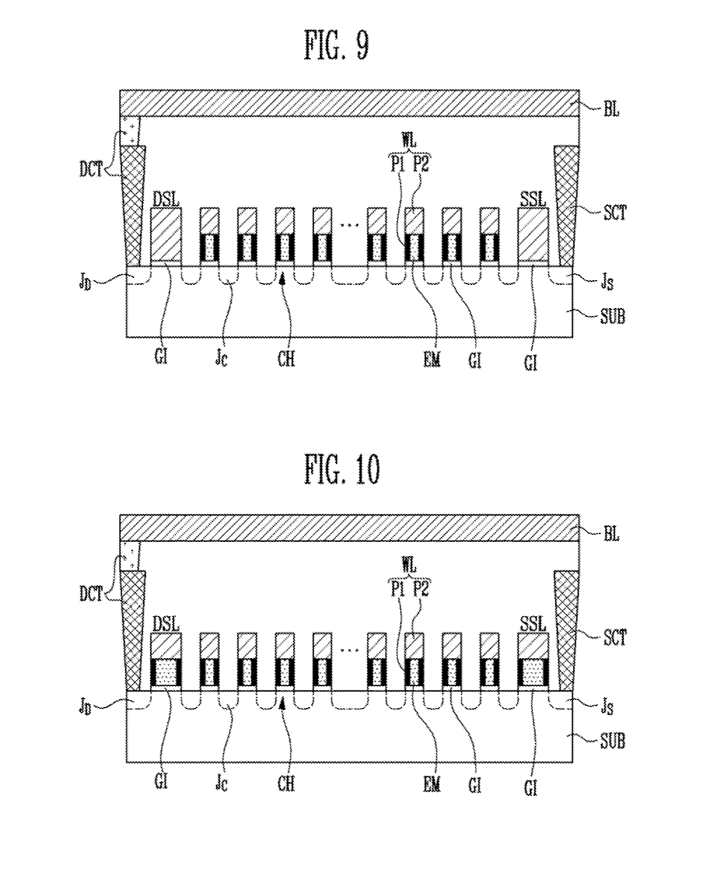

FIG. 10 is a cross-sectional view illustrating a semiconductor device according to an exemplary embodiment of the present invention. The semiconductor device illustrated in FIG. 10 is the same as the semiconductor device described above with reference to FIG. 9 except for the structures of the first select line SSL and the second select line DSL.

Referring to FIG. 10, the first select line SSL and the second select line DSL may be disposed with word lines WL interposed therebetween. The first select line SSL and the second select line DSL may include the same structure as the world line WL including the first and second conductive patterns P1 and P2 and the EM pattern EM disposed therein. In this case, the first and second select lines SSL and DSL may be simultaneously formed with the word lines WL. The nonvolatile memory device illustrated in FIG. 10 may be formed by using the process described above with reference to FIG. 9.

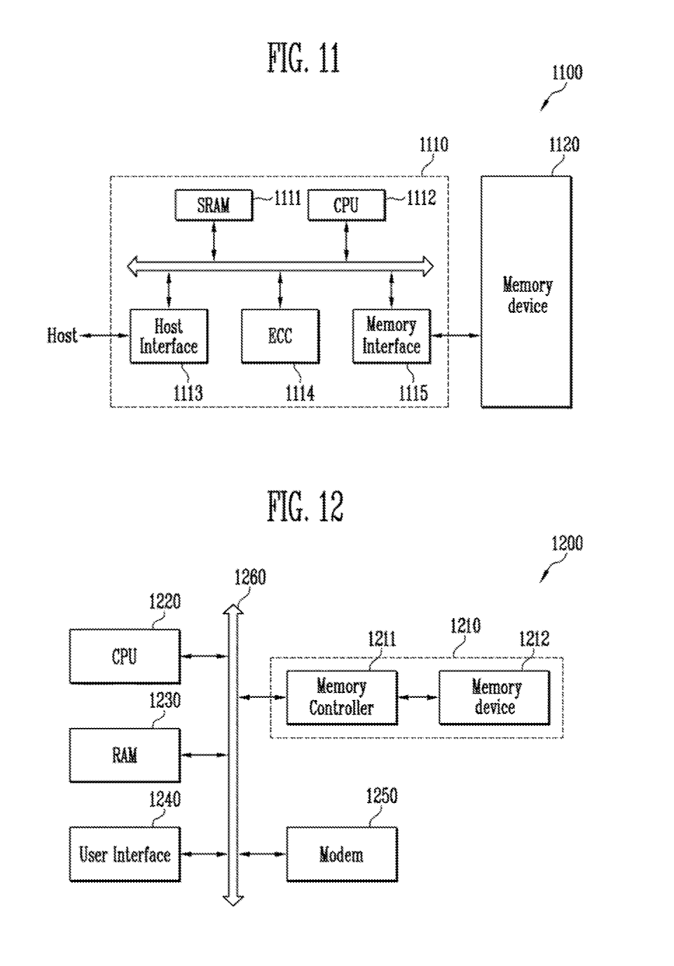

FIG. 11 is a block diagram illustrating a memory system according to an exemplary embodiment of the present invention.

Referring to FIG. 11, a memory system 1100 according to the embodiment of the present invention may include a memory device 1120 and a memory controller 1110.

The memory device 1120 may include the nonvolatile memory device according to the exemplary embodiments described with reference to FIGS. 1A to 10. Further, the memory device 1120 may be a multi-chip package formed of a plurality of flash memory chips.

The memory controller 1110 may control the memory device 1120, and may include an SRAM 1111, a CPU 1112, a host interface 1113, an ECC 1114, and a memory interface 1115. The SRAM 1111 may be used as an operational memory of a CPU 1112, the CPU 1112 may perform a general control operation for a data exchange of the memory controller 1110, and a host interface 1113 may include a data exchange protocol of a host connected with the memory system 1100. Further, the ECC 1114 may detect and correct an error included in data read from the memory device 1120, and the memory interface 1115 may perform interfacing with the memory device 1120. In addition, the memory controller 1110 may further include a ROM for storing code data for interfacing with the host.

As described above, the memory system 1100 including the above described structure may be a memory card or a Solid State Disk (SSD), in which the memory device 1120 is combined with the memory controller 1110. For example, when the memory system 1100 is an SSD, the memory controller 1110 may communicate with an external device (for example, a host) through one of various interface protocols, such as USB, MMC, PCI-E, SATA, PATA, SCSI, ESDI, and IDE.

FIG. 12 is a block diagram illustrating a computing system according to an exemplary embodiment of the present invention.

Referring to FIG. 12 a computing system 1200 according to the exemplary embodiment of the present invention may include a CPU 1220, a RAM 1230, a user interface 1240, a modem 1250, and a memory system 1210, which are electrically connected to a system bus 1260. Further, in a case where the computing system 1200 is a mobile device, the computing system 1200 may further include a battery for supplying an operational voltage to the computing system 1200, and may further include an application chip-set, a CMOS image sensor CIS, a mobile DRAM, and the like.

The memory system 1210 may be formed of a memory device 1212 and a memory controller 1211 as previously described with reference to FIG. 11.

Embodiments have been disclosed in the drawings and the specification as described above. The specific terms used herein are for purposes of illustration and do not limit the scope of the present invention as defined by the claims. Accordingly, those skilled in the art will appreciate that various modifications and another equivalent examples may be made without departing from the scope and spirit of the present disclosure. Therefore, the sole scope of technical protection of the present invention will be defined by the technical spirit of the accompanying claims.

What is claimed is:

1. A semiconductor device, comprising:
a channel layer;
a gate insulating layer formed on a surface of the channel layer;
a cell gate pattern formed along the gate insulating layer; and
an Electro Migration (EM) pattern formed in the cell gate pattern, and movable according to an electric field formed between the cell gate pattern and the channel layer.

2. The semiconductor device of claim 1, wherein the cell gate pattern is formed to open one surface of the EM pattern adjacent to the gate insulating layer.

3. The semiconductor device of claim 1, wherein the cell gate pattern includes:
a first conductive pattern opening a first surface of the EM pattern adjacent to the gate insulating layer, and formed on a surface of the EM pattern; and
a second conductive pattern facing the gate insulating layer with the EM pattern and the first conductive pattern interposed therebetween.

4. The semiconductor device of claim 3, wherein the first conductive pattern surrounds remaining surfaces of the EM pattern except for the first surface.

5. The semiconductor device of claim 3, wherein the first conductive pattern surrounds remaining surfaces of the EM pattern except for the first surface and a second surface of the EM pattern facing the first surface.

6. The semiconductor device of claim 3, wherein the first conductive pattern is formed of the same conductive material or a different conductive material from that of the second conductive pattern.

7. The semiconductor device of claim 3, wherein the first conductive pattern includes at least one of Ti, TiN, Ta, TaN, and tungsten.

8. The semiconductor device of claim wherein the second conductive pattern includes tungsten.

9. The semiconductor device of claim 1, wherein the channel layer is formed in a straight pillar structure surrounded by the gate insulating layer, the cell gate pattern, and the EM pattern.

10. The semiconductor device of claim 1, wherein the channel layer includes:
two or more straight pillar parts; and
a pipe part connecting the straight pillar parts.

11. The semiconductor device of claim 10, further comprising a pipe gate surrounding the pipe part.

12. The semiconductor device of claim 1, wherein the channel layer semiconductor substrate.

13. The semiconductor device of claim 12, further comprising cell junction regions formed within the semiconductor substrate at both sides of the cell gate pattern, and including an impurity.

14. The semiconductor device of claim 1, further comprising a first select line and a second select line formed in a structure different from that of the cell gate pattern, and formed at both ends of the channel layer with the cell gate pattern interposed therebetween.

15. The semiconductor device of claim 1, further comprising a first select line and a second select line having the same structure as the cell gate pattern and the EM pattern, and formed at both ends of the channel layer with the cell gate pattern interposed therebetween.

16. The semiconductor device of claim 1, wherein the EM pattern includes one or more of aluminum and copper.

17. A method of operating a semiconductor device, comprising:
performing a program operation on a memory cell, which includes a channel layer, a gate insulating layer formed on a surface of the channel layer, a gate pattern formed along the gate insulating layer, and an EM pattern formed in the gate pattern, by applying a first voltage to the channel layer, and a second voltage to the gate pattern so that an air gap is formed between the EM pattern and the gate insulating layer.

18. The method of claim 17, wherein the second voltage is higher than the first voltage.

19. A method of operating a semiconductor device, comprising:
performing an erase operation on a memory cell, which includes a channel layer, a gate insulating layer formed on a surface of the channel layer, a gate pattern formed along the gate insulating layer, and an EM pattern formed in the gate pattern, by applying a third voltage to the channel layer, and a fourth voltage to the gate pattern so that an air gap is formed between the EM pattern and the gate pattern and the EM pattern is in contact with the gate insulating layer.

20. The method of claim 19, wherein the third voltage is higher than the fourth voltage.
